(19) United States
(12) Patent Application Publication
(10) Pub. No.: US 2011/0024155 A1
(43) Pub. Date: Feb. 3, 2011

(54) Device For Securing Household Systems From Young Children

(75) Inventors: Kevin Brantley, Gilbert, AZ (US); Derek Underhill, Tempe, AZ (US)

Correspondence Address: Morgan Law Offices, PLC, 4635 S. Lakeshore Dr. Suite 131, Tempe, AZ, 85282, US

(73) Assignee: Kevin Brantley, Gilbert, AZ (US)

(21) Appl. No.: 12/534,125

(22) Filed: Aug. 1, 2009

(51) Int. Cl. H05K 5/03

(52) U.S. Cl. 174/67; 220/242

(57) ABSTRACT

A device for securing electrical outlets, switches, telephone jacks, computer network outlets, etc., from the reach of a young child is provided. The device can be easily installed over any standard outlet or switch. The device is made as a single piece and comprises a first portion adapted to substantially cover the outlet or switch but leaving access to it, a second portion adapted to cover the first portion such that the outlet or switch is no longer accessible when the second portion is in a closed position, and a third portion, between the first portion and the second portion, forming a living hinge allowing the device to bend along a line of the hinge. The device further includes a child-resistant lock. Preferably, the device has a sleek design and protrudes no more than necessary (e.g., in the case of an electrical outlet, no more than one-half inch) from the wall when installed. Thus, the device will not only secure the outlet but also camouflage it from an inquisitive child looking for objects in the room to play with.

### FIELD OF THE INVENTION

The present invention relates to a device for securing electrical outlets, light switches, telephone jacks, computer network outlets, etc., from the reach of young children.

### BACKGROUND

Electrical outlets are potentially dangerous attractions for young children. They are ordinarily easily reachable by toddlers and can be quite dangerous. Each year some children die of electrocution while “playing” with electrical outlets.

To address this problem, many parents fit their indoor electric outlets with plastic outlet protectors. However, many children are able to remove outlet protectors. In one study, it was found that 47 percent of 4-year-olds and 31 percent of 2-year-olds were able to remove outlet protectors with a round, flat face and two prongs.

Various other devices have been developed to address the problem. However, these devices tend to be bulky, cumbersome, or expensive to manufacture.

Likewise, young children are attracted to light switches, cable TV jacks, data jacks, and coaxial data jacks, etc. While not as potentially dangerous as electrical outlets, playing with these can be a nuisance and require frequent parental intervention.

Accordingly, there is a need for an improved device for securing household systems from young children.

### SUMMARY OF THE INVENTION

According to a preferred embodiment of the present invention, a device for securing electrical outlets, light switches, telephone jacks, computer network outlets, etc., from the reach of a young child is provided. The device can be easily installed over any standard outlet or switch. The device is made as a single piece and comprises a first portion adapted to substantially cover the outlet or switch but leaving access to it, a second portion adapted to cover the first portion such that the outlet or switch is no longer accessible when the second portion is in a closed position, and a third portion, between the first portion and the second portion, forming a living hinge allowing the device to bend along a line of the hinge. The device further includes a child-resistant lock.

Preferably, the device has a sleek design and protrudes no more than necessary (e.g., in the case of an electrical outlet, no more than one-half inch) from the wall when installed. Thus, the device will not only secure the outlet but also camouflage it from an inquisitive child looking for objects in the room to play with.

Preferably, the device is made from a single piece of plastic, such as polypropylene or polyethylene. Because the third portion acts as a living hinge, preferably, the third portion is on average thinner than the other parts of the device allowing for easy bending. Preferably, the device is manufactured using an injection molding process. Preferably, the living hinge is coined and flexed several times after being removed from the mold and while still relatively hot. Preferably, the lock is snap lock.

These and other aspects, features, and advantages of the present invention will become apparent from the following detailed description of preferred embodiments, which is to be read in connection with the accompanying drawings.

### BRIEF DESCRIPTION OF THE DRAWINGS

FIG. 1 shows an exemplary device for securing an electrical outlet installed on an indoor electrical outlet;

FIG. 2 shows the exemplary device for securing an electrical outlet in an open position;

FIG. 3 shows the exemplary device for securing an electrical outlet in an open position being accessible to electrical sockets;

FIG. 4 shows the exemplary device for securing an electrical outlet in a closed position;

FIG. 5 shows a close-up perspective of an exemplary snap lock for the device;

FIG. 6 shows a close-up perspective of an exemplary living hinge for the device; and

FIG. 7 shows another view of the exemplary device.

### DETAILED DESCRIPTION

While the accompanying drawings show a particular preferred embodiment of the present invention, it is to be appreciated that they are meant to be illustrative, not limiting. Although the drawings and accompanying description disclose a device useable to secure an electrical outlet, it is to be appreciated that other preferred embodiments of the present invention relate to devices used to cover other types of outlets or switches attractive to young children, such as light switches, telephone jacks, cable TV jacks, computer networks outlets, etc. Furthermore, it is to be understood that although electrical outlets having two electrical sockets are shown throughout, it is to be understood that the present invention can also be utilized for electrical outlets having more, or fewer, sockets, or where the sockets are arranged differently. Furthermore, although certain types of plastics have been described as being suitable to mold the device, other types of plastic could also be used. Additionally, it is to be understood that various other types of child-resistant locks besides the “snap lock” type described herein may be used. For example, instead of, or in addition to, a snap lock, a lock requiring a key may be used.

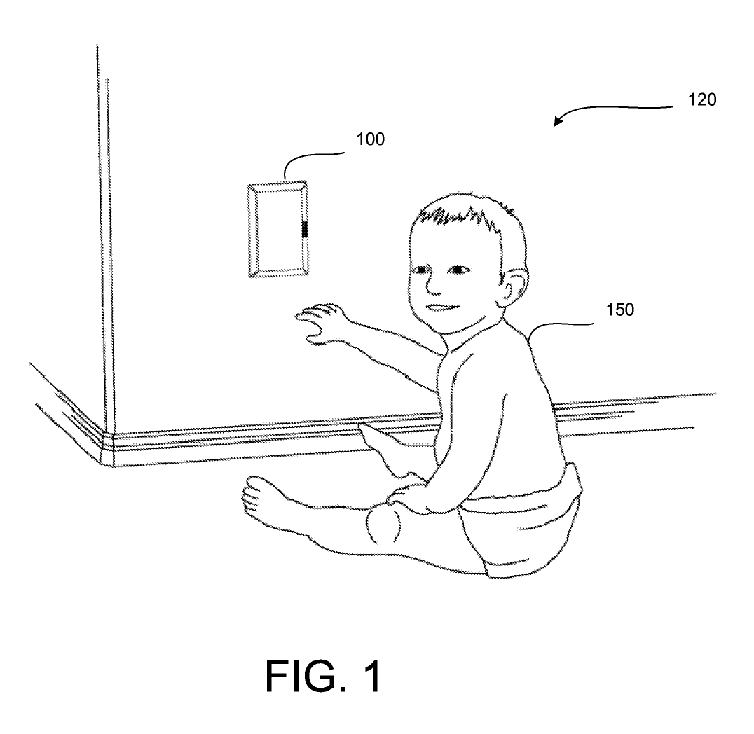

As depicted in FIG. 1, an exemplary device for securing an electrical outlet 100 is shown installed over an indoor electrical outlet. As will be described in greater detail, the device 100 prevents access by a young child to an electrical outlet by completely covering the electrical outlet. Thus, the child, such as a baby 170, is prevented from electrical injury that could have resulted from insertion of a finger or placement of an object into the electrical outlet. The device 100 includes a child-resistant lock 150 so that young children are unable to open it. The device 100 has a low profile such that it protrudes no more than one-half inch from the wall making it is less attractive to an inquisitive child.

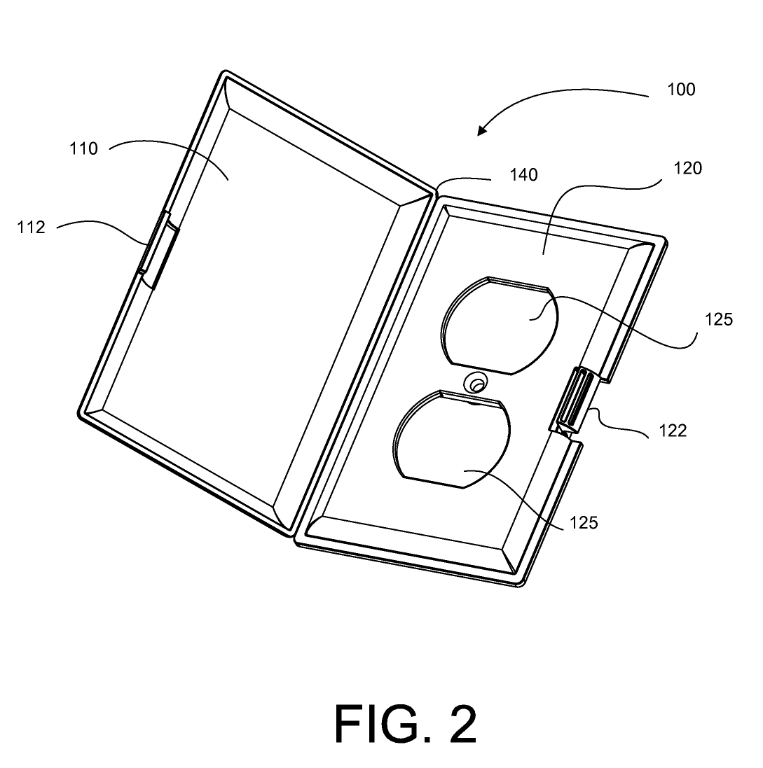

FIG. 2 shows the device for securing an electrical outlet 100 in more detail. As illustrated, the device 100 includes a plate 120, a cover 110, and a hinge 140. The plate 120 can be sized to fit over any standard electrical outlet (but may be custom-sized to fit a non-standard outlet, if desired). The plate 120 can be screwed into, or otherwise attached to, an electrical outlet in the same manner as a conventional electrical outlet plate. The cover 110 is sized to fit over the plate 120, to enclose the plate. The hinge 140, situated between the plate 120 and the cover 110, as shown, allows the cover 110 to swing, thus assuming either an open position or a closed position. Preferably, the device 100 is made entirely from a single piece of material, preferably, plastic, such as, for example, polyethylene or polypropylene. Preferably, the device is manufactured using an injection molding process. Preferably, the manufacture does not require an assembly step because the device is made in one piece.

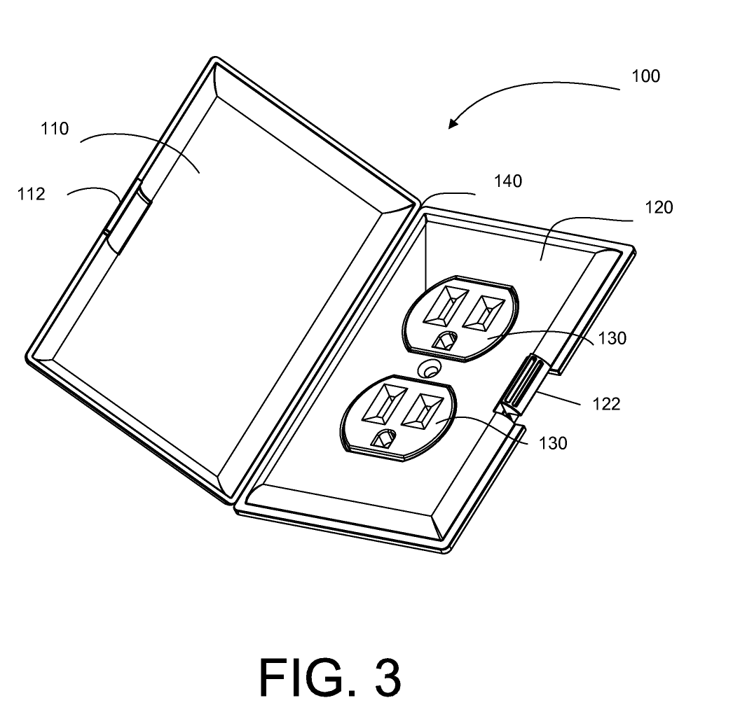

As illustrated in FIG. 2, the device 100 is in an open position. In the open position, the child-resistant lock 150 is separated into its constituent parts: a male element 122 and a female element 112, as shown. That is, the male element 122 and the female element 112 are not inter-locked when in the open position. When the device 100 is open, the electrical outlet is accessible. The plate 120 includes socket holes 125 for each electrical socket of the electrical outlet, as shown. Referring to FIG. 3, the socket holes 125 allow access to electrical sockets 130. Thus, an electrical appliance can be plugged into the outlet when the device 100 is in the open position.

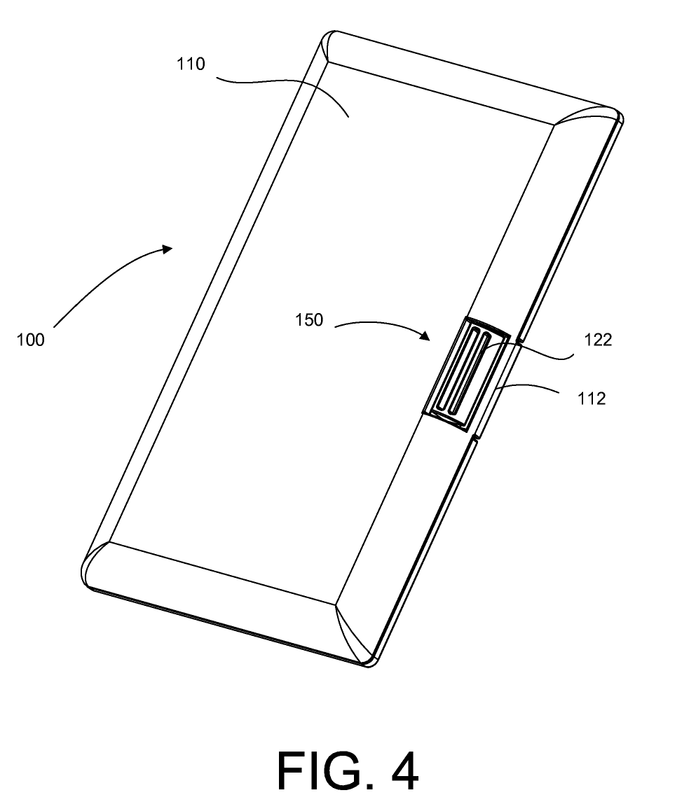

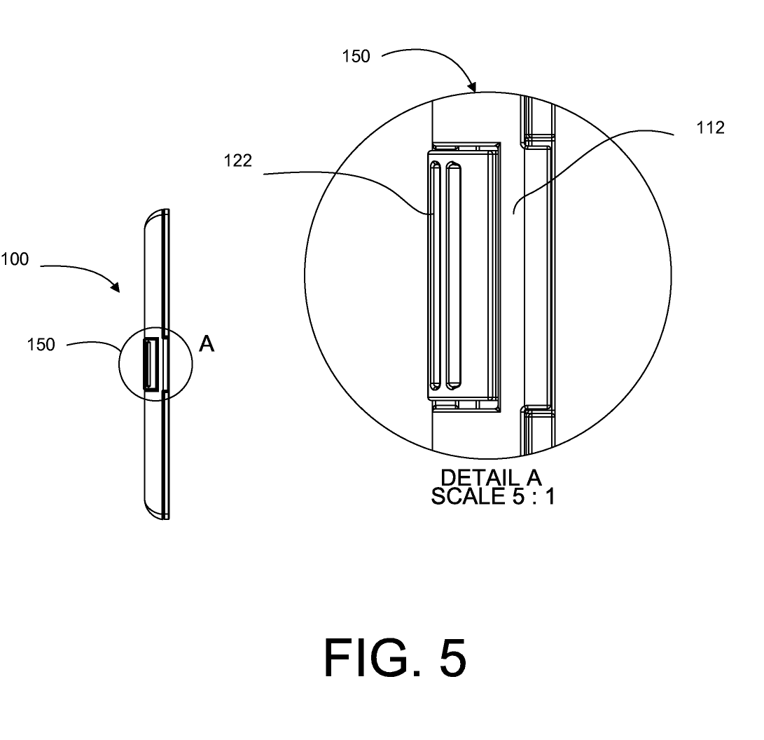

FIG. 4 shows the device for securing an electrical outlet 100 in a closed position. FIG. 5 shows a close-up perspective of the child-resistant lock 150 while the device 100 is closed. In this closed position, as shown particularly in Detail A, the child-resistant lock 150 is locked by way of the male element 122 being inserted into the female element 112, forming a friction fit, as shown. In the closed position, the cover 110 encloses the plate 120 making the electrical sockets 130 inaccessible. Because the child-resistant lock 150 cannot be opened by a young child, the electrical outlet is secured and the child can safely play in the room without any danger of an electrical injury.

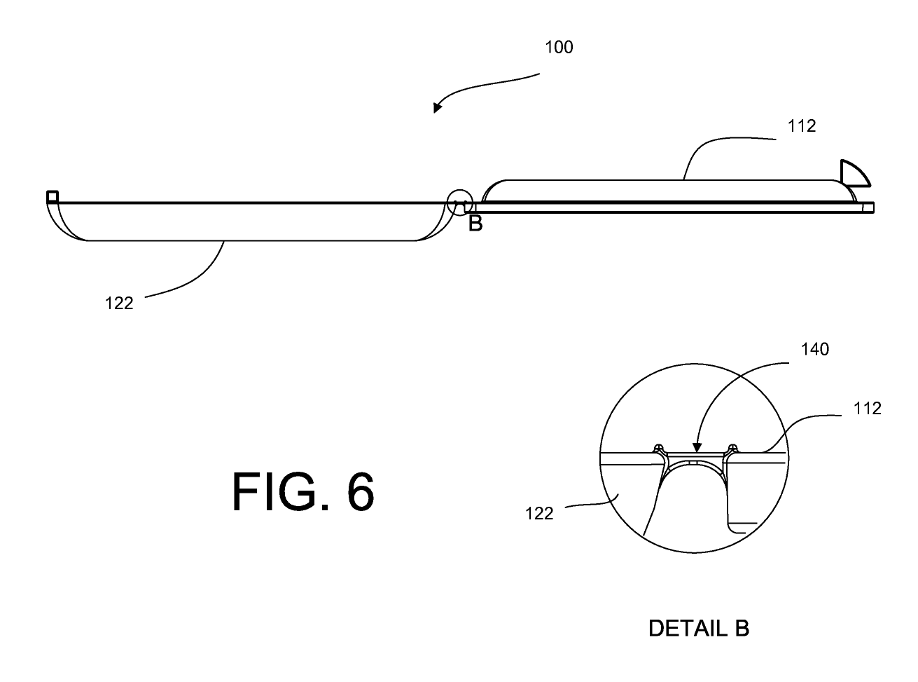

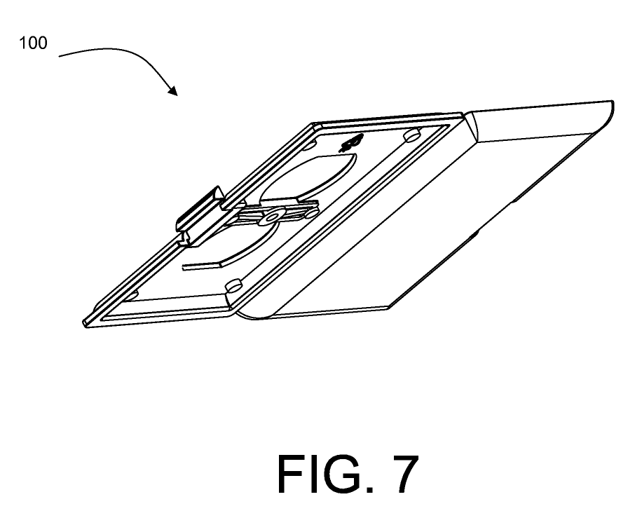

FIG. 6 shows a close-up perspective of an exemplary hinge 140 useable for the device. As depicted, particularly in Detail B, the hinge 140 is a “living hinge”. A living hinge is formed as a thin section of plastic that connects two segments of a part to keep them together and allow the part to be opened and closed. Preferably, the hinge 140 is, on average, thinner than the rest of the device 100. Preferably, to orient the fibers for increased life, when the hinge 140 comes out of the mold and still relatively hot, the hinge 140 is plastically deformed (coined) and flexed several times. FIG. 7 illustrates the degree to which the hinge 140 allows the device to bend.

While this invention has been described in conjunction with the various exemplary embodiments outlined above, it is evident that many alternatives, modifications and variations will be apparent to those skilled in the art. Accordingly, the exemplary embodiments of the invention, as set forth above, are intended to be illustrative, not limiting. Various changes may be made without departing from the spirit and scope of the invention.

What is claimed is:

1. A device for securing an outlet, comprising:
a single piece, including
a first portion adapted to substantially cover the outlet leaving access to the outlet;
a second portion adapted to enclose the first portion such that the outlet is no longer accessible when the second portion is in a closed position; and
a third portion, between the first portion and the second portion, forming a living hinge allowing the first portion and the second portion to bend along a line of the hinge.

2. The device of claim 1, wherein the single piece is plastic.

3. The device of claim 2, wherein the plastic is polypropylene.

4. The device of claim 2, wherein the plastic is polyethylene.

5. The device of claim 1, wherein the third portion is on average thinner than the other portions.

6. The device of claim 1, wherein the device is manufactured using an injection molding process.

7. The device of claim 6, wherein the third portion is coined.

8. The device of claim 6, wherein the third portion is flexed a plurality of times after being removed from a mold and still hot.

9. The device of claim 6, wherein, after the injection molding process, an assembly step is not required.

10. The device of claim 1, further including a lock, the lock structured and arranged to secure the cover in the closed position.

11. The device of claim 10, wherein the lock is child-resistant.

12. The device of claim 10, wherein the lock is a snap lock.

13. The device of claim 12, wherein the snap lock includes inter-lockable parts.

14. The device of claim 1, wherein, when installed, the device protrudes no more than about one half inch from a wall.

15. The device of claim 1, wherein the outlet is an electrical outlet.

16. The device of claim 1, wherein the outlet is a telephone jack.

17. The device of claim 1, wherein the outlet is a network jack.

18. A device for securing an electrical switch, comprising:
a single piece, including
a first portion adapted to substantially cover the electrical switch leaving access to the electrical switch;
a second portion adapted to enclose the first portion such that the electrical switch is no longer accessible when the second portion is in a closed position; and
a third portion, between the first portion and the second portion, forming a living hinge allowing the first portion and the second portion to bend along a line of the hinge.

19. A device for securing an electrical outlet, comprising:
a single piece of plastic material, including
a first portion adapted to substantially cover the electrical outlet leaving access to one or more electrical sockets;
a second portion adapted to enclose the first portion such that the one or more electrical sockets is no longer accessible when the second part is in a closed position; and
a third portion, between the first portion and the second portion, the third portion forming a hinge.
